(19) United States
(12) Patent Application Publication
(10) Pub. No.: US 2026/0360412 A1
(43) Pub. Date: Nov. 12, 2026

(54) MEMORY DEVICE WITH CARVE OUT MEMORY REGION

(71) Applicant: Rambus Inc., San Jose, CA (US)

(72) Inventor: Thomas Vogelsang, Jericho, VT (US)

(21) Appl. No.: 19/667,638

(22) Filed: May 4, 2026

Related U.S. Application Data
(60) Provisional application No. 63/803,171, filed on May 9, 2025.

(51) Int. Cl. G11C 11/4093; G11C 11/4091; G11C 29/52

(52) U.S. Cl. CPC G11C 11/4093; G11C 11/4091; G11C 29/52

(57) ABSTRACT

A memory device is configurable between operating modes that have different effective row address spaces and different access widths. The memory device includes a main region and carve out region. In a normal operation mode, the main region and the carve out region function similarly such that memory device operates with a row address space corresponding to its total number of rows spanning both regions, and an access width corresponding to a row access width in either region. In a carve out operation mode, the memory device operates according to a row address space of only the main region. Memory operations involve accessing bits of the main region and concurrently accessing bits from a row segment in the carve out region, thereby increasing the effective access width relative to the normal operation mode.

### CROSS-REFERENCE TO RELATED APPLICATIONS

This application claims the benefit of U.S. Provisional Application No. 63/803,171 filed on May 9, 2025, which is incorporated by reference herein.

### BRIEF DESCRIPTION OF THE DRAWINGS

The teachings of the embodiments herein can be readily understood by considering the following detailed description in conjunction with the accompanying drawings.

FIG. 1 is an example embodiment of a memory system.

FIG. 2 is a diagram illustrating example modes for operating a memory bank.

FIG. 3 is an example embodiment of a layout of a memory bank.

FIG. 4 is an example embodiment of switching logic associated with local sense amplifiers of a memory bank.

FIG. 5A is an example embodiment of switching logic associated with local sense amplifiers in a carve out region of a memory bank under a first operating scenario.

FIG. 5B is an example embodiment of switching logic associated with local sense amplifiers in a carve out region of a memory bank under a second operating scenario.

FIG. 5C is an example embodiment of switching logic associated with local sense amplifiers in a carve out region of a memory bank under a third operating scenario.

FIG. 5D is an example embodiment of switching logic associated with local sense amplifiers in a carve out region of a memory bank under a fourth operating scenario.

FIG. 6 is an example embodiment of a memory module.

FIG. 7 is a flowchart illustrating an example method for operating a memory device.

### DETAILED DESCRIPTION

A memory device is configurable between operating modes that have different effective row address spaces and different access widths. The memory device includes a main region and carve out region. In a normal operation mode, the main region and the carve out region function similarly such that memory device operates with a row address space corresponding to its total number of rows spanning both regions, and an access width corresponding to a row access width of a row in either region. In a carve out operation mode, the memory device operates according to a row address space of only the main region. Memory operations involve accessing bits of the main region and concurrently accessing bits from a row segment in the carve out region, thereby extending the effective access width relative to the normal operation mode. In the carve out operation mode, the carve out region may be utilized to store extra payload bits to enable extended word lengths relative to the normal operation mode or may be utilized to store metadata bits associated with the payload bits. Examples of metadata may include parity bits for error correction and/or detection, status bits, configuration bits, or other metadata.

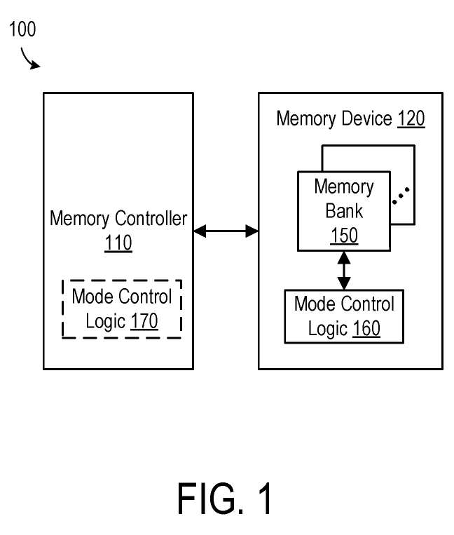

FIG. 1 illustrates an example embodiment of a memory system 100 that includes a memory controller 110 and a memory device 120 that may have multiple memory banks 150. The memory controller 110 controls memory operations of the memory device 120 such as write operations, read operations, refresh operations, and various mode control operations. In a write operation, the memory controller 110 issues a write command that includes a write address to the memory device 120 together with write data for writing to the write address. In response to the write command, the memory device 120 writes the write data to the specified write address within one of the memory banks 150. In a read operation, the memory controller 110 issues a read command that includes a read address. In response to the read command, the memory device 120 obtains read data from the read address of a memory bank 150 and sends the read data to the memory controller 110. The memory controller 110 may optionally include mode control logic 170 that generates various mode control commands to the memory device 120 described further herein. The mode control logic 170 may be omitted in implementations where the mode of the memory device 120 is configured independently of the memory controller 110.

The memory device 120 may comprise a dynamic random-access memory (DRAM) device or other type of memory device. The memory device 120 may include a set of banks 150 for data storage and mode control logic 160 for controlling an operating mode of the memory banks 150. The different modes enable the memory banks 150 to operate with different effective row address spaces and different effective access widths. For example, in one implementation, the mode control logic 160 enables switching between a normal operation mode and a carve out operation mode. In the carve out operation mode, the memory bank 150 may operate with a reduced row address space relative to the normal operation mode and with a higher effective access width relative to the normal operation mode. The carve out mode operation may be achieved by the memory bank performing an access to a row in the reduced row address space and concurrently accessing extra bits in a carve out region of memory that is outside of the reduced row address space. In various applications, these extra bits may represent additional payload bits (to achieve longer effective word size), error correction code bits associated with error detection and/or correction, status bits, or other metadata bits.

In one implementation, the mode control logic 160 of the memory device 120 may control the operating mode based on a mode control command received from the mode control logic 170 of the memory controller 110. In another implementation, the mode control logic 160 may control the operating mode based on a signal on an external mode control pin. In yet another implementation, the mode control logic 160 may control the operating mode based on a non-volatile programmable register or physical switch that may be configured at the time of manufacture. In various embodiments, the operating mode may be configurable at the bank level (i.e., the mode may be independently configured for each bank 150), at the device level (i.e., the mode is the same for all banks 150), or at the memory module level (i.e., the mode is the same for all devices 120 in a memory module).

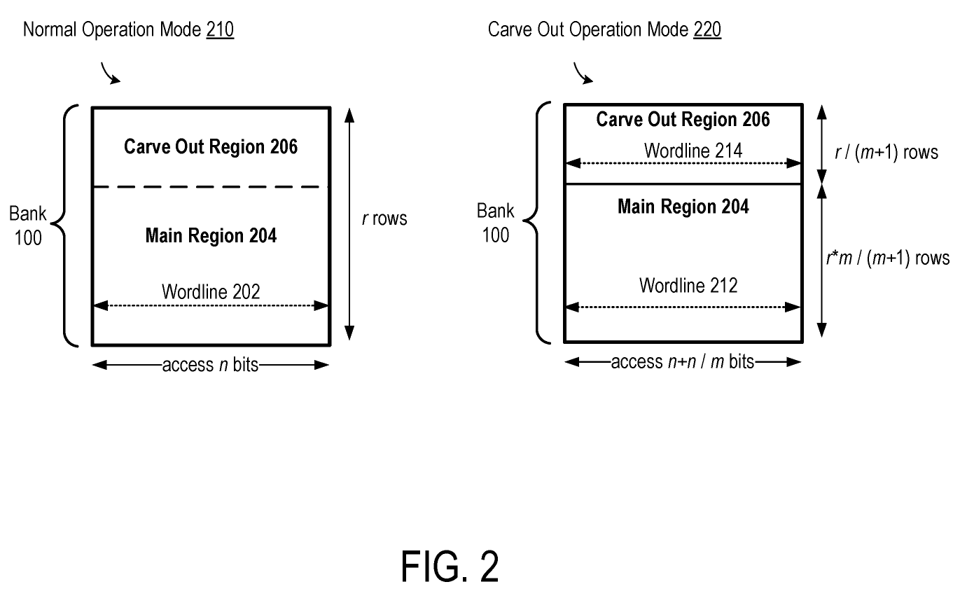

FIG. 2 illustrates a logical structure of a bank 150 that is operable in either a normal operation mode 210 or a carve out operation mode 220. The bank 150 includes an array of cells organized into rows and columns. The bank 150 may include a main region 204 of memory cells and a carve out region 206 of memory cells. For example, a bank 150 may include a total of r rows with a ratio m representing the number of rows in the main region 204 relative to the number of rows in the carve out region 206. For example, if m=4, the main region 204 includes four times the number of rows as the carve out region 206. More generally, the number of rows in main region 204 is given by r*m / (m+1) and the number of rows in the carve out region 206 is given by r / (m+ 1).

In the normal operation mode 210, the carve out region 206 functions the same as the main region 204 from the perspective of the memory controller 110. A memory access involves activating a single wordline 202 of the bank 150 based on a row address of a memory command and accessing n bits of the row corresponding to the active wordline 202. The active wordline 202 may correspond to any of the r rows of the bank 150 in either the main region 204 or the carve out region 206.

In the carve out operation mode 220, the effective row address space (from the perspective of the memory controller 110) is reduced to the row address space of the main region 204 (e.g., r*m / (m+1) rows). Each memory access involves activating a wordline 212 in the main region 204 based on the row address of the memory command and concurrently activating a wordline 214 in the carve out region 206 that has a predefined correspondence to the row address of the wordline 212 in the main region 204. Each operation involves accessing n bits from the row of the active wordline 212 of the main region 204 and concurrently accessing an extra n / m bits from the row of the associated wordline 214 in the carve out region 206. Thus, a memory access yields a total of n + n / m bits. The ratio of the number of bits n from the main region 204 to the number of extra bits n / m from the carve out region 206 is the same ratio m that defines the relative sizes of the main region 204 and the carve out region 206. For example, if m = 4, then an operation in the carve out operation mode 220 involves accessing four times the number of bits from the main region 204 as the carve out region 206. In one such configuration, a row of the carve out region 206 logically contains m segments that each correspond to a different full row of a group of m rows in the main region 204. For example, a row R_{c}of the carve out region may include segments r_{c1}, r_{c2}, r_{c3}, r_{c4} (for m = 4) where segment r_{c1}is accessed together with a full row Rₘ₁ of the main region, segment r_{c2}is accessed together with a row R m2 of the main region, segment r_{c3}is accessed together with a row Rₘ₃ of the main region, and segment r_{c4}is accessed together with a row Rₘ₄ of the main region. The rows Rₘ₁, Rₘ₂, Rₘ₃, Rₘ₄ in this example may be consecutive rows of the main region 204 or may be non-consecutive rows.

The total number of accessible bits of the bank 150 remains the same in the normal operation mode 210 and the carve out operation mode 220. However, the row address space is relatively larger in the normal operation mode 210 than the carve out operation mode 220, while the access width is relatively larger in the carve out operation mode 220 than in the normal operation mode 210. In some embodiments, the carve out region 206 and the main region 204 may be sized such that the row address space in the carve out operation mode 220 is more than half of the row address space in the normal operation mode 210 and the access width in the carve out operation mode 220 is larger than but less than twice the access width of the normal operation mode 210 (i.e., m > 1). In various embodiments, the bank 150 may be configured with m = 2, m = 4, m = 8, m = 16, or a different value.

In an example implementation, each row of the bank 150 may additionally include on-die error correction coding (ECC) bits for enabling error detection and/or correction of the n bits when operating in the normal operating mode 210. When operating in the carve out operation mode 220, the ECC bits associated with the rows in the carve out region 206 may be ignored (since only a subset of bits of a row in the carve out region 206 is accessed at a time), and the ECC bits associated with the row in the main region 204 may be used as ECC bits for the entire extended word of n + n / m length.

In an example application for the carve out operation mode 220, the main region 204 may be utilized to store payload data and the carve out region 206 may be used to store metadata associated with the payload data. Examples of metadata may include parity bits for error detection and/or correction associated with payload data, status bits to provide status information in network memory systems, access control bits to manage data security associated with the payload data, or other metadata. In other example applications, the carve out region 206 may store additional payload bits that do not necessarily have distinct function from the bits stored in the main region 204. For example, operating in the carve operation mode enables an effective extended word size of n + n / m payload bits instead of the normal word size of n payload bits per access in the normal operation mode.

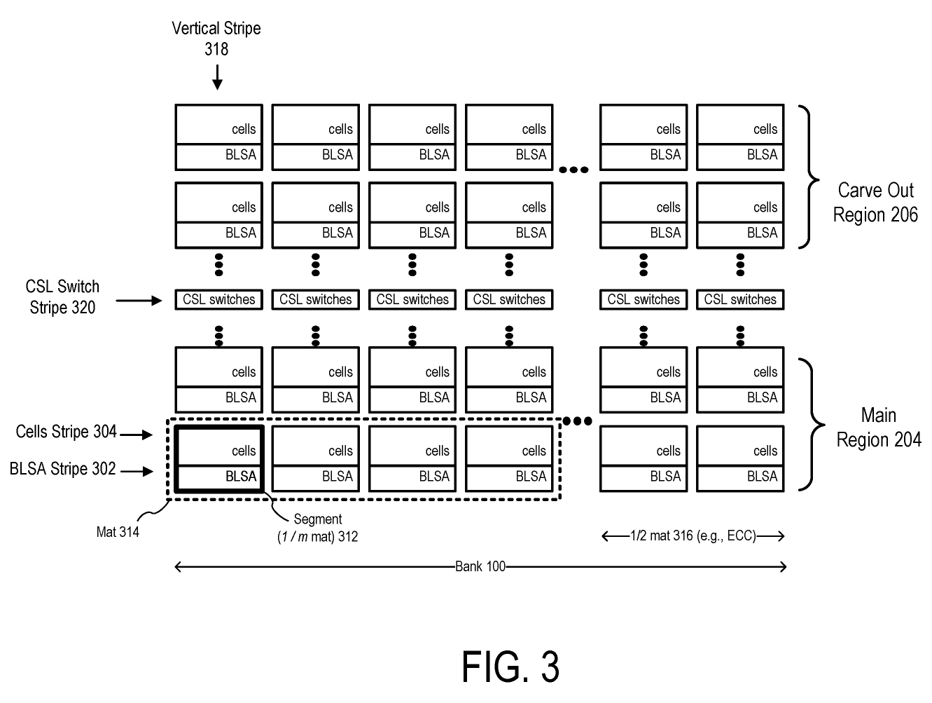

FIG. 3 illustrates an example layout for a bank 150 that can operate in either the normal operation mode 210 or the carve out operation mode 220 described above. In this example layout, the bank 150 includes a set of mats 314 that each include one or more stripes of cells 304 (comprising a set of rows) and at least one stripe of local bitline sense amplifiers (BLSA) 302 that perform local sensing for the one or more stripes of cells 304 within the mat 314. In a practical implementation, the BLSA stripe 302 is not necessarily located at an edge of the cell stripe 304 and may instead bifurcate a set of cell stripes 304. In other implementations, a mat 314 may have multiple distributed BLSA stripes 302.

The mat 314 may be logically divided into m segments 312 (e.g., m = 4 evenly sized segments 312). The segments 312 may be arranged in vertical stripes 318 (across multiple mats 314) that share data and control lines. For example, a vertical stripe 318 may include 256 bitlines (BLs) and 64 column select lines (CSLs) (of which one CSL is activated per memory access) that are shared by the segments 312 within the vertical stripe 318. Each vertical stripe 318 may enable access to four data bits per access on respective global data (GDQ) lines that span the segments 312 in the vertical stripe 318. This layout results in 1024 bitlines per mat 314 and 16 GDQ lines per mat 314. The full memory bank 150 may include eight mats 314 for payload data. The bank 150 may also include an extra ½ mat 316 for parity bits, thereby enabling 128 payload bits and 8 parity bits per access. In alternative implementations, the bank 150 may include different arrangements of bitlines, GDQ lines, CSLs, and mats 314 to enable banks 150 of different storage capacity and access widths.

To enable switching between the normal operation mode 210 and the carve out operation mode 220 described above, the bank 150 also includes a horizonal stripe of column select line (CSL) switches 320 between the main region 204 the carve out region 206 that couple or decouple the corresponding CSLs between the regions 204, 206. As will be described in further detail below, these CSL switches 320 are all closed when operating in the normal operation mode 210 to achieve continuity of the CSLs in the main region 204 and the carve out region 206 (i.e., the same CSL operate the same in the main region 204 and the carve out region 206). In the carve out operation mode 220, only a subset of CSL switches 320 are closed. For example, 1 / m of the CSL switches 308 may be closed during a memory access in the carve out operation mode 220 with the active CSL switches 308 evenly distributed across the segments 312.

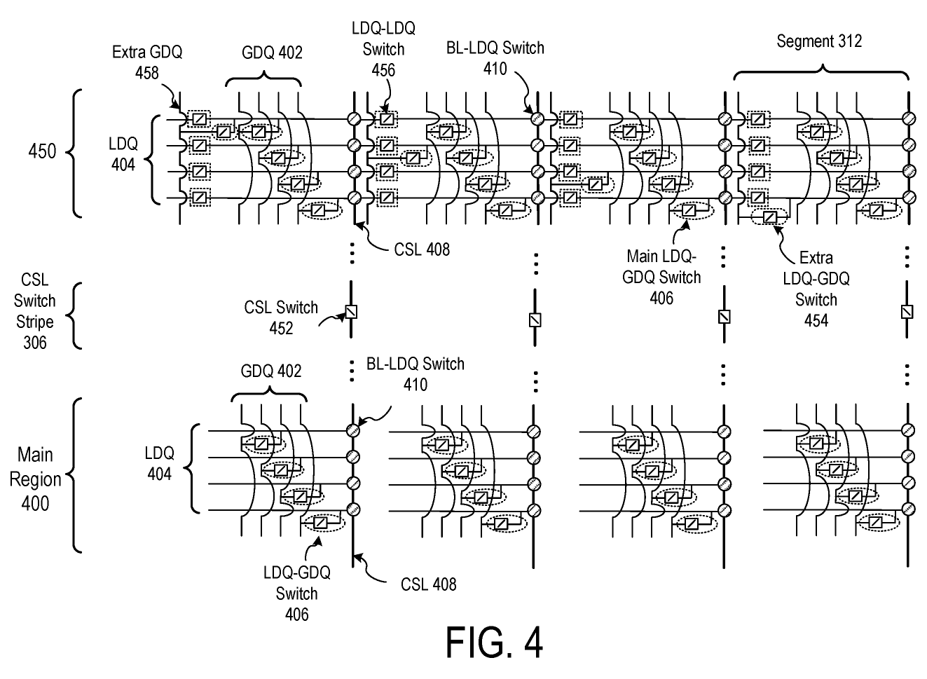

FIG. 4 illustrates BLSA switching logic 400 in the main region 204 and BLSA switching logic 450 in the carve out region 206 for a set of segments 312 within a mat 314. In both regions 204, 206, the switching logic 400, 450 includes a set of CSLs 408, a set of local data (LDQ) lines 404 (of which each LDQ line may be implemented as a differential pair), a set of GDQ lines 402 (of which each GDQ line may be implemented as a differential pair), a set of BL-LDQ switches 410, and a set of LDQ-GDQ switches 406.

The CSLs 408 control the BL-LDQ switches 410 to select which BLs are connected to the respective LDQ lines 404 depending on the column address of a memory command. For example, in an implementation with 256 BLs and 64 CSLs per vertical stripe 318, the BL-LDQ switches 410 each select between 64 BLs, resulting in 4-bit accesses per segment 312 on each set of LDQ lines 404. The LDQ lines 404 operate to transport data signals within each segment 312 between the selected BLs and the set of GDQ lines 402 via the respective LDQ-GDQ switches 406. The LDQ-GDQ switches 406 couple or decouple the LDQ lines 404 to the GDQ lines 402 depending on whether or not there is an active wordline in the mat 314. The LDQ-GDQ switches close when there is an active wordline in the mat 314, and the LDQ-GDQ switches open when there is no active wordline in the mat 314. The GDQ lines 402 are shared across each vertical stripe 318 and operate to transfer data signals to and from external input/output (I/O) logic of the bank 150.

The switching logic 450 in the carve out region 206 includes an extra GDQ line 458 per segment 312 and an extra LDQ-GDQ switch 454 per segment 312. In each of the m segments 312, the extra LDQ-GDQ switch 454 is positioned between a different one of the LDQ lines 404 and the extra GDQ line 458.

A set of CSL switches 452 operate to couple or decouple CSLs 408 in the carve out region 206 to or from the corresponding CSLs 408 in the main region 204. The CSL switches 452 operate to control which CSLs 408 in the carve out region 206 can be active during a memory access. For example, 1 / m of the CSL switches 452 may be closed during the carve out operation mode 220 (one per vertical stripe 318) such that only 1 / m CSLs 408 in the carve out region 206 relative to the main region 204.

When operating in the normal operation mode 210, the extra LDQ-GDQ switches 454 are open, thereby decoupling the LDQ lines 404 from the extra GDQ lines 458. Thus, the extra GDQ line 458 is not used. When operating in the carve out operation mode 220, the extra LDQ-GDQ switches 454 couples different ones of the LDQ line 404 to the extra GDQ line 458 per segment 312 such that the extra GDQ lines 458 transport data to and from the carve out region 206 concurrently with the main GDQ lines 402 transporting data to and from the main region 204. This enables the extended access width of the carve out operation mode 220.

The switching logic 450 in the carve out region 206 also includes a set of LDQ-LDQ switches 456 that couple or decouple adjacent LDQ lines 404 across the segments 312 in the mat 314. These LDQ-LDQ switches 456 are open when operating in the normal operation mode 210, thereby isolating the respective LDQ lines 404 in each segment 312. The LDQ-LDQ switches 456 are closed when operating in the carve out operation mode 220, such that each of the bridged LDQ lines 404 will each transport data for to one of the extra GDQ lines 458.

FIG. 4 illustrates an embodiment in which the extra switching logic and lines (e.g., extra GDQ line 458, LDQ-LDQ switches 456, and extra LDQ-GDQ switches 454) are absent from the main region 400. In an alternative implementation, the LDQ-LDQ switches 456, extra LDQ-GDQ switches 454, and extra GDQ lines 458 may be present but disabled in the main region 400 regardless of the operation mode. Furthermore, additional CSL stripes 320 may be distributed throughout the bank 150. Thus, in this implementation, the physical implementation of both regions is the same, and the respective sizes of the main region 204 and the carve out region 206 may be dynamically controlled by configuring how the extra switching logic operates.

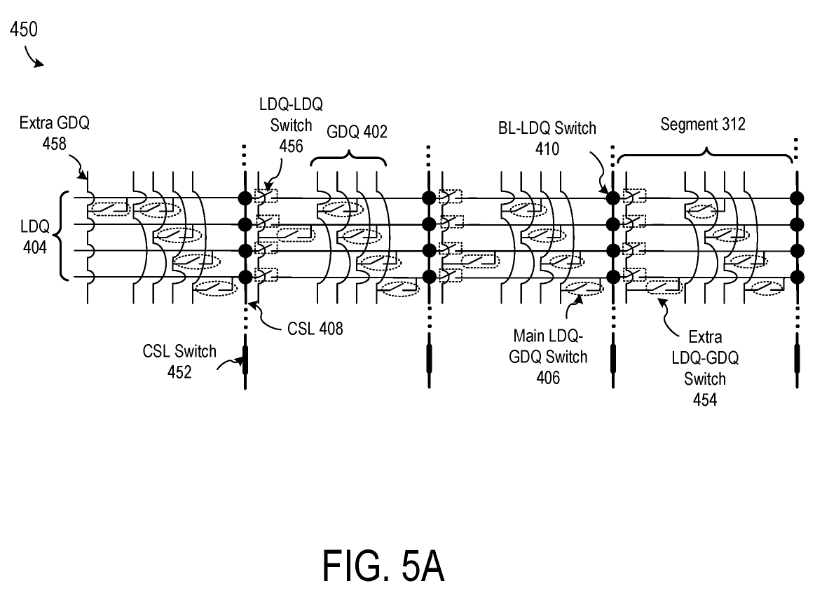

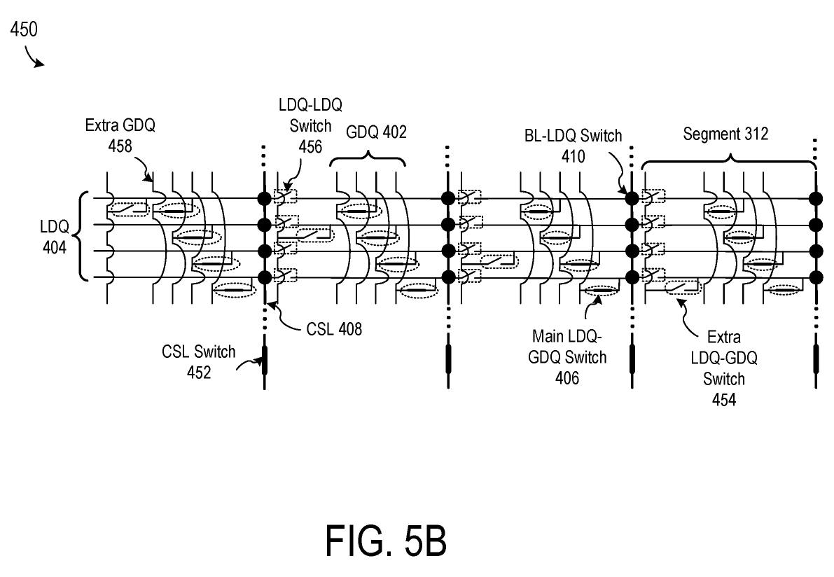

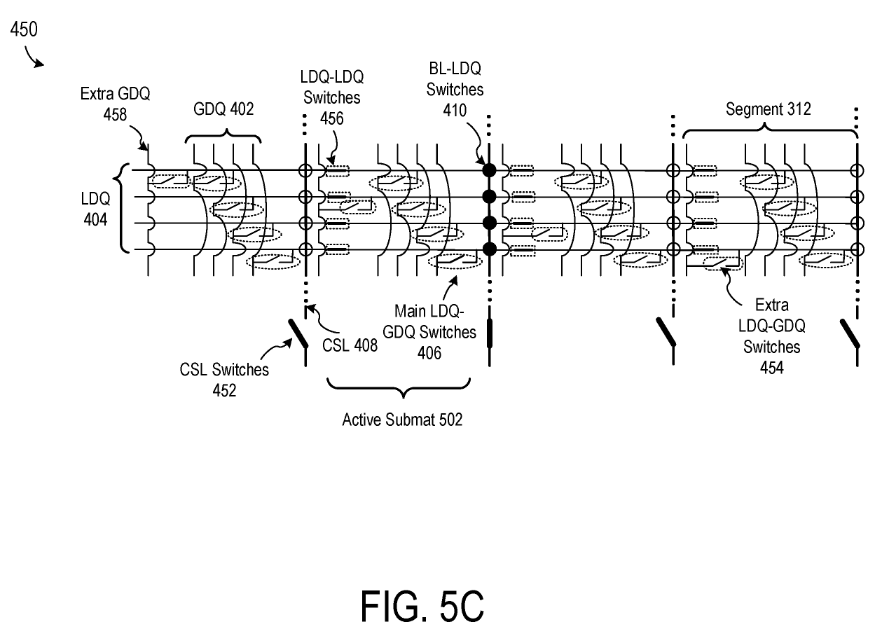

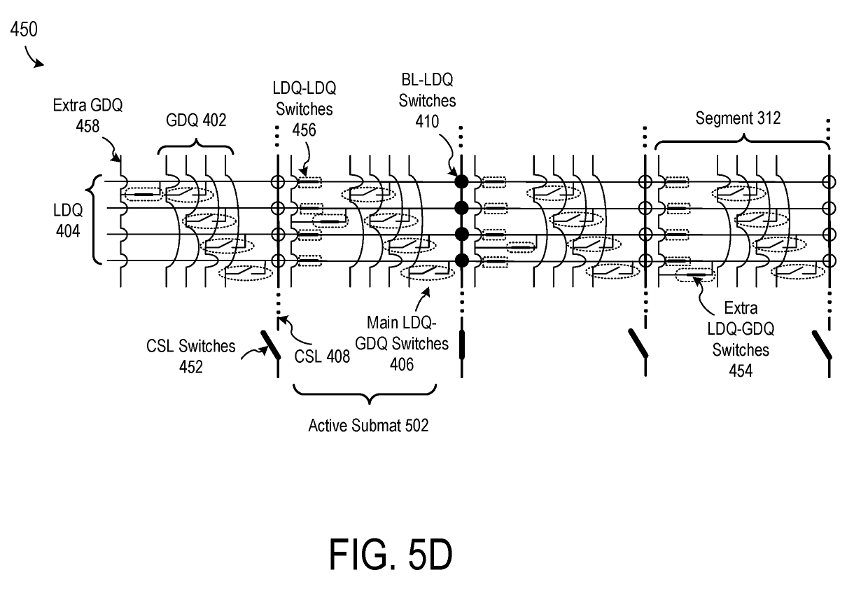

FIGS. 5A-D illustrate example configurations of the switching logic 450 in the carve out region 206 under different operating scenarios.

FIGS. 5A-5B illustrate the switching configuration in the normal operation mode 210 with FIG. 5A showing the switching configuration when there is no active wordline in the mat 314, and FIG. 5B showing the configuration when there is an active wordline in the mat 314. In both configurations, the CSL switches 452 are all closed such that the CSLs 408 in the carve out region 206 each connect to the corresponding CSLs 408 in the main region 204. Columns are therefore selected in the carve out region 206 based on the column address in the same manner as in the main region 204. Furthermore, the LDQ-LDQ switches 456 and the extra LDQ-GDQ switches 454 are all open to isolate the LDQ lines 404 in each segment 312 from each other and from the extra GDQ lines 458, which are not used in the normal operation mode 210. The main LDQ-GDQ switches 406 are controlled depending on whether or not there is an active wordline in the segment 312 in the same way as in the main region 104. In FIG. 5A, there is no active wordline and the main LDQ-GDQ switches 406 are therefore all open, freeing the GDQ lines 402 for transporting data associated with other segments 312 in the same vertical stripe 318. In FIG. 5B, the mat 314 has an active wordline and the main LDQ-GDQ switches 406 therefore all close to enable the GDQ lines 402 to access the respective LDQ lines 404 within the segment 312.

FIGS. 5C-D illustrate the switching configuration in the carve out operation mode 220, with FIG. 5C showing the switching configuration when there is no active wordline in the mat 314, and FIG. 5D illustrating the switching configuration when there is an active wordline in the mat 314. In both configurations, only one of CSL switches 452 is closed and the other CSL switches 452 are open. This enables access to only a subset of bitlines in the carve out region 206 (via the active BL-LDQ switches 410). For example, one out of every m CSL switches 452 are closed thereby enabling access to 1 / m bitlines relative to main region 204. The LDQ-LDQ switches 456 are closed in the carve out operation mode 220 to bridge respective LDQ lines 404 across the segments 312. In FIG. 5C, there is no active wordline in the mat 314 and therefore the main LDL-GDQ switches 406 and the extra LDQ-GDQ switches 454 are open, thereby freeing the main GDQ lines 402 and the extra GDQ lines 458 to transport data associated with other segments 312 within the same vertical stripe 318. In FIG. 5D, the extra LDL-GDQ switches 455 are closed, thereby enabling the extra GDQ lines 458 to access the respective bridged LDQ lines 404 (bridged across the full mat 314).

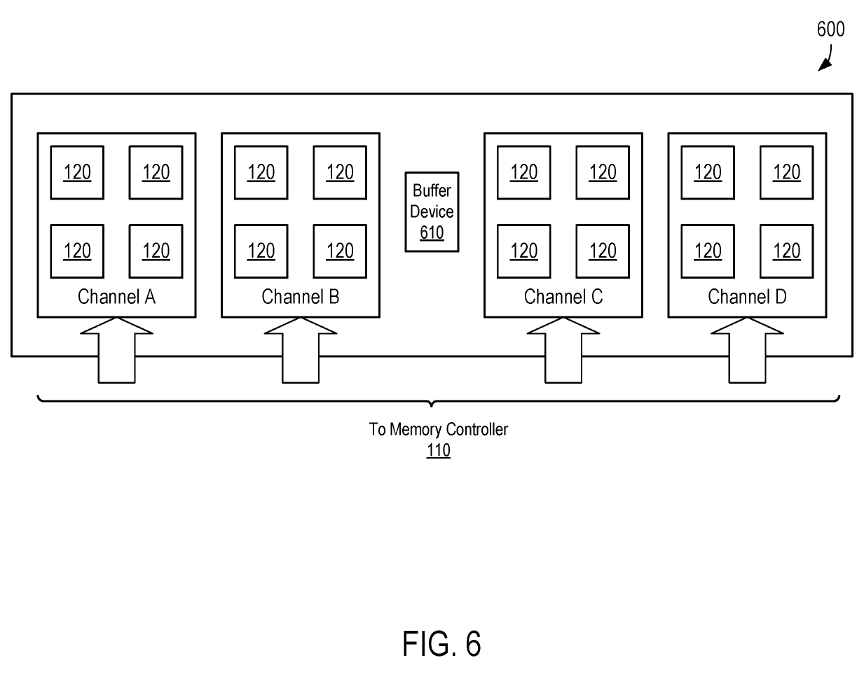

FIG. 6 illustrates an example embodiment of a memory module 600 incorporating a plurality of memory devices 120 that may each be configurable to operate in a normal operation mode 210 or a carve out operation mode 220. The memory module 600 includes a buffer device 610 and a plurality of memory devices 120 organized into channels. The buffer device 610 communicates command/address, clock, or other control signals (not shown) between a memory controller 110 and the set of memory devices 120. In this example, the memory module 600 comprises four channels (e.g., channels A-D) that may independently communicate with the memory controller 110 and four memory devices 120 per channel. Alternative embodiments may include different numbers of channels or different numbers of memory devices 200 per channel. In various embodiments, the operation mode may be configurated at the memory module level, at the device level, or at the bank level.

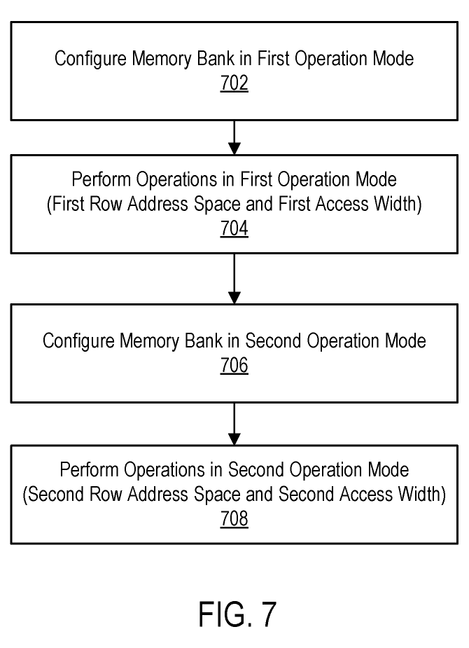

FIG. 7 illustrates an example embodiment of a process for operating a memory device 120. A memory bank 150 of a memory device 120 is configured 702 in a first operation mode (e.g., a normal operation mode 210). The memory bank 150 performs 704 one or more memory operations in the first operation mode in which the memory bank 150 operates according to a first row address space and a first access width. For example, when operating in the normal operation mode 210, the mode control logic 160 operates to close all of the CSL switches 452 such that all CSLs 408 associated with a column address of a memory command are active in the carve out region 206. The mode control logic 160 furthermore inactivates the set of LDQ-LDQ switches 456 in and the set of extra LDQ-GDQ switches 454 in the carve out region 206. The main LDQ-GDQ switches 406 in the carve out region 206 operate in the same manner as in the main region 104 and are activated when a wordline of the mat 314 is active (and otherwise inactivated to free the GDQ line 402 for data transport to and from other mats 314).

The memory bank 150 is subsequently reconfigured 706 in a second operation mode (e.g., a carve out operation mode 220) and additional memory operations are performed 708. Here, the memory bank 150 operates according to a second row address space that is a subset of the first row address space and includes more than half than the first row address space, and the memory bank operates according to a second access width that is larger than and less than twice than the first access width. A total number of accessible bits of the memory bank are substantially the same in the first operation mode and the second operation mode.

When operating in the carve out operation mode 220, the mode control logic 160 operates to close only a subset of the CSL switches 452 such that only a subset of the CSLs 408 associated with the column address of a memory command are active in the carve out region 206 (i.e., one segment 312 per mat 314). The mode control logic 160 furthermore inactivates the main LDQ-GDQ switches 406 in the carve out region 206, actives the set of LDQ-LDQ switches 456 in the carve out region and controls activation of the set of extra LDQ-GDQ switches 454 in the carve out region 206 such that they are active when a wordline of the mat 314 is active (and are otherwise inactive to free the extra GDQ lines 458 to transport data associated with other mats 314).

Upon reading this disclosure, those of ordinary skill in the art will appreciate still alternative structural and functional designs and processes for the described embodiments, through the disclosed principles of the present disclosure. Thus, while embodiments and applications of the present disclosure have been illustrated and described, it is to be understood that the disclosure is not limited to the precise construction and components disclosed herein. Various modifications, changes and variations which will be apparent to those skilled in the art may be made in the arrangement, operation and details of the method and apparatus of the present disclosure herein without departing from the scope of the disclosure as defined in the appended claims.

What is claimed is:

1. A memory device, comprising:
a memory bank; and
mode control logic to switch operation of the memory bank between a first operation mode and a second operation mode,
wherein, in the first operation mode, the memory bank operates according to a first row address space and a first access width, and
wherein, in the second operation mode, the memory bank operates according to second row address space that is a subset of the first row address space and includes more than half than the first row address space, and the memory bank operates according to a second access width that is larger than and less than twice than the first access width, and wherein a total number of accessible bits of the memory bank are substantially the same in the first operation mode and the second operation mode.

2. The memory device of claim 1,
wherein the memory bank is organized into a main region and a carve out region, wherein rows in the main region and the carve out region collectively correspond to the first row address space, and wherein the rows in the main region correspond to the second row address space that is the subset of the first row address space, and
wherein the memory bank is organized into a main region and a carve out region, wherein the first access width corresponds to an access width of a row in either the main region or the carve out region, and wherein the second access width corresponds to a combination of the access width of the row in the main region and a segment of a row in the carve out region.

3. The memory device of claim 2, wherein during the second operation mode, the segment of the row in the carve out region is accessed together with the row of the main region based on a predefined association with a same row address.

4. The memory device of claim 3, wherein the row of the main region stores payload bits and wherein the segment of the row in the carve out region stores metadata bits associated with the payload bits.

5. The memory device of claim 3, wherein during the first operation mode, the memory bank stores error correction or detection bits encoding error correction or detection information for corresponding rows of the main region and the carve out region, and wherein during the second operation mode, error correction or detection bits associated with each respective row of the main region encode error correction or detection information associated with a combined word of the row in the main region and the segment of the row in the carve out region.

6. The memory device of claim 1, wherein the first row address space comprises r rows, the first access width comprises n bits, the second row address space comprises r*m / (m + 1) rows for a constant m and the second access width comprises n + n / m bits.

7. The memory device of claim 1,
wherein the memory bank is organized into a main region and a carve out region, and wherein the memory bank includes a set of column select line switches to couple or decouple column select lines in the main region and the carve out region dependent on whether the memory bank is operating in the first operation mode or the second operation mode,
wherein in the first operation mode, all of the column select line switches are closed such that all column select lines associated with a column address of a memory command are active in the carve out region, and
wherein in the second operation mode, only a subset of the column select line switches are closed such that only a subset of the column select lines associated with the column address of a memory command are active in the carve out region.

8. The memory device of claim 7, wherein a stripe of bitline sense amplifiers for a mat in the carve out region includes:
a set of local data lines in each of a plurality of segments of the mat;
a set of main global data lines in each of the plurality of segments of the mat, wherein the main global data lines span multiple mats in a vertical stripe of the memory bank;
a set of extra global data lines that span the multiple mats in the vertical stripe of the memory bank;
a set of bitline to local data line (BL-LDQ) switches per segment to couple or decouple bitlines to the local data lines dependent on an active column select line (CSL);
a set of local data line to main global data line (main LDQ-GDQ) switches per segment to couple or decouple the local data lines to respective main global data lines, wherein the main LDQ-GDQ switches are active in the first operation mode when a wordline of the mat is active, are inactive in the first operation mode when no wordline of the mat, and are inactive in the second operation mode;
a set of local data line to local data line (LDQ-LDQ) switches to couple or decouple local data lines across the plurality of segments in the mat, wherein the set of LDQ-LDQ switches are inactive in the first operation mode and are active in the second operation mode; and
a set of local data line to extra global data line (extra LDQ-GDQ) switches to couple or decouple the local data lines to the set of extra global data lines, wherein the set of extra LDQ-GDQ switches are inactive in the first operation mode, are inactive in the second operation mode when no wordline of the mat is active, and are active in the second operation mode when a wordline of the mat is active.

9. A memory module, comprising:
a set of memory devices organized into one or more channels, wherein each of the set of memory devices comprises:
a memory bank;
mode control logic to switch operation of the memory bank between a first operation mode and a second operation mode,
wherein, in the first operation mode, the memory bank operates according to a first row address space and a first access width, and
wherein, in the second operation mode, the memory bank operates according to second row address space that is a subset of the first row address space and includes more than half than the first row address space, and the memory bank operates according to a second access width that is larger than and less than twice than the first access width, and wherein a total number of accessible bits of the memory bank are substantially the same in the first operation mode and the second operation mode; and
a buffer device to communicate control signals between a memory controller and the set of memory devices.

10. The memory module of claim 9,
wherein the memory bank is organized into a main region and a carve out region, wherein rows in the main region and the carve out region collectively correspond to the first row address space, and wherein the rows in the main region correspond to the second row address space that is the subset of the first row address space, and
wherein the first access width corresponds to an access width of a row in either the main region or the carve out region, and wherein the second access width corresponds to a combination of the access width of the row in the main region and a segment of a row in the carve out region.

11. The memory module of claim 10, wherein during the second operation mode, the segment of the row in the carve out region is accessed together with the row of the main region based on a predefined association with a same row address.

12. The memory module of claim 11, wherein the row of the main region stores payload bits and wherein the segment of the row in the carve out region stores metadata bits associated with the payload bits.

13. The memory module of claim 11, wherein during the first operation mode, the memory bank stores error correction or detection bits encoding error correction or detection information for corresponding rows of the main region and the carve out region, and wherein during the second operation mode, error correction or detection bits associated with each respective row of the main region encode error correction or detection information associated with a combined word of the row in the main region and the segment of the row in the carve out region.

14. The memory module of claim 9, wherein the first row address space comprises r rows, the first access width comprises n bits, the second row address space comprises r*m / (m + 1) rows for a constant m and the second access width comprises n + n / m bits.

15. The memory module of claim 9,
wherein the memory bank is organized into a main region and a carve out region, and wherein the memory bank includes a set of column select line switches to couple or decouple column select lines in the main region and the carve out region dependent on whether the memory bank is operating in the first operation mode or the second operation mode,
wherein in the first operation mode, all of the column select line switches are closed such that all column select lines associated with a column address of a memory command are active in the carve out region, and
wherein in the second operation mode, only a subset of the column select line switches are closed such that only a subset of the column select lines associated with the column address of a memory command are active in the carve out region.

16. The memory module of claim 15, wherein a stripe of bitline sense amplifiers for a mat in the carve out region includes:
a set of local data lines in each of a plurality of segments of the mat;
a set of main global data lines in each of the plurality of segments of the mat, wherein the main global data lines span multiple mats in a vertical stripe of the memory bank;
a set of extra global data lines that span the multiple mats in the vertical stripe of the memory bank;
a set of bitline to local data line (BL-LDQ) switches per segment to couple or decouple bitlines to the local data lines dependent on an active column select line (CSL);
a set of local data line to main global data line (main LDQ-GDQ) switches per segment to couple or decouple the local data lines to respective main global data lines, wherein the main LDQ-GDQ switches are active in the first operation mode when a wordline of the mat is active, are inactive in the first operation mode when no wordline of the mat, and are inactive in the second operation mode;
a set of local data line to local data line (LDQ-LDQ) switches to couple or decouple local data lines across the plurality of segments in the mat, wherein the set of LDQ-LDQ switches are inactive in the first operation mode and are active in the second operation mode; and
a set of local data line to extra global data line (extra LDQ-GDQ) switches to couple or decouple the local data lines to the set of extra global data lines, wherein the set of extra LDQ-GDQ switches are inactive in the first operation mode, are inactive in the second operation mode when no wordline of the mat is active, and are active in the second operation mode when a wordline of the mat is active.

17. A method of operating a memory device comprising:
configuring a memory bank in a first operation mode;
performing one or more memory operations in the first operation mode in which the memory bank operates according to a first row address space and a first access width;
configuring the memory bank in a second operation mode; and
performing one or more memory operations in the second operation mode in which the memory bank operates according to a second row address space that is a subset of the first row address space and includes more than half than the first row address space, and the memory bank operates according to a second access width that is larger than and less than twice than the first access width, and wherein a total number of accessible bits of the memory bank are substantially the same in the first operation mode and the second operation mode.

18. The method of claim 17,
wherein the memory bank is organized into a main region and a carve out region, wherein rows in the main region and the carve out region collectively correspond to the first row address space, and wherein the rows in the main region correspond to the second row address space that is the subset of the first row address space, and
wherein the first access width corresponds to an access width of a row in either the main region or the carve out region, and wherein the second access width corresponds to a combination of the access width of the row in the main region and a segment of a row in the carve out region.

19. The method of claim 17,
wherein the memory bank is organized into a main region and a carve out region, and wherein the memory bank includes a set of column select line switches to couple or decouple column select lines in the main region and the carve out region dependent on whether the memory bank is operating in the first operation mode or the second operation mode,
wherein configuring the memory bank in the first operation mode comprises closing all of the column select line switches such that all column select lines associated with a column address of a memory command are active in the carve out region; and
wherein configuring the memory bank in the second operation mode comprises closing only a subset of the column select line switches such that only a subset of the column select lines associated with the column address of a memory command are active in the carve out region.

20. The method of claim 19,
wherein a stripe of bitline sense amplifiers for a mat in the carve out region includes:
a set of local data lines in each of a plurality of segments of the mat, a set of main global data lines in each of the plurality of segments of the mat, wherein the main global data lines span multiple mats in a vertical stripe of the memory bank,
a set of extra global data lines that span the multiple mats in the vertical stripe of the memory bank,
a set of bitline to local data line (BL-LDQ) switches per segment to couple or decouple bitlines to the local data lines dependent on an active column select line (CSL),
a set of local data line to main global data line (main LDQ-GDQ) switches per segment to couple or decouple the local data lines to respective main global data lines,
a set of local data line to local data line (LDQ-LDQ) switches to couple or decouple local data lines across the plurality of segments in the mat, and
a set of local data line to extra global data line (extra LDQ-GDQ) switches to couple or decouple the local data lines to the set of extra global data lines;
wherein configuring the memory bank in the first operation mode comprises:
activating the main LDQ-GDQ switches in the carve out region when a wordline of the mat is active and inactivating the main LDQ-GDQ switches when no wordline of the mat is active,
inactivating the set of LDQ-LDQ switches in the carve out region, and
inactivating the set of extra LDQ-GDQ switches in the carve out region; and
wherein configuring the memory bank in the second operation mode comprises:
inactivating the main LDQ-GDQ switches in the carve out region,
activating the set of LDQ-LDQ switches in the carve out region,
activating the set of extra LDQ-GDQ switches in the carve out region when a wordline of the mat is active and inactivating the set of extra LDQ-GDQ switches in the carve out region when no wordline of the mat is active.
